(19) United States
(12) Patent Application Publication
(10) Pub. No.: US 2022/0069184 A1
(43) Pub. Date: Mar. 3, 2022

(54) SEMICONDUCTOR LIGHT EMITTING DEVICE AND METHOD FOR MANUFACTURING THE SAME

(71) Applicant: SL VIONICS CO., LTD., Gyeonggi-do (KR)

(72) Inventors: Kyoung Min KIM, Gyeonggi-do (KR); Gye Oul JEONG, Gyeonggi-do (KR); Eun Hyun PARK, Gyeonggi-do (KR)

(21) Appl. No.: 17/414,503

(22) PCT Filed: Jan. 31, 2020
(86) PCT No.: PCT/KR2020/001450

§ 371 Date: Jun. 16, 2021

(30) Foreign Application Priority Data
Jan. 31, 2019 (KR) 10-2019-0013070
Oct. 14, 2019 (KR) 10-2019-0126931

(51) Int. Cl. H01L 33/62; H01L 25/075; H01L 25/16; H01L 29/866; H01L 33/54; H01L 33/00

(52) U.S. Cl. CPC H01L 33/62; H01L 25/0753; H01L 25/167; H01L 2933/0066; H01L 33/54; H01L 33/005; H01L 2933/005; H01L 29/866

(57) ABSTRACT

Disclosed is a semiconductor light emitting device comprising at least one semiconductor light emitting chip, with each chip including a plurality of electrodes; a plurality of pads arranged at a designated distance from the plurality of electrodes on a plane, respectively; electrical connections provided on the same plane as the plurality of pads for electrically connecting the electrodes and the pads, respectively; and an encapsulation member for covering the at least one semiconductor light emitting chip.

### TECHNICAL FIELD

The present disclosure relates generally to a semiconductor light emitting device with a lower probability of open-circuited and a method for manufacturing the same.

Further, the present disclosure relates to a semiconductor light emitting device capable of emitting lights from six sides.

### BACKGROUND

This section provides background information related to the present disclosure which is not necessarily prior art. Directional terms, such as “upper”, “lower”, “above”, “below” or others used herein are defined with respect to the directions shown in the drawings.

FIG. 1 shows an example of a semiconductor light emitting chip in the prior art.

The semiconductor light emitting device includes a growth substrate 11 (e.g., a sapphire substrate), and a stack of layers sequentially deposited on the growth substrate 11, including a buffer layer 12, a first semiconductor layer 13 having a first conductivity (e.g., an n-type GaN layer), an active layer 14 for generating light by electron-hole recombination (e.g., an InGaN/(In)/GaN multiple quantum well (MQW) structure), and a second semiconductor layer 15 having a second conductivity different from the first conductivity (e.g., a p-type GaN layer). The semiconductor light emitting device further includes a light transmitting conductive film 16 for current spreading on the second semiconductor layer 15, an electrode 17 serving as a pad formed on the light transmitting conductive film 16, and an electrode 18 serving as a pad formed on an etched exposed portion of the first semiconductor layer 13 (e.g., a stack of Cr/Ni/Au metallic pads). This particular type of the semiconductor light emitting device as shown in FIG. 1 is called a lateral chip. Here, one side of the growth substrate 11 serves as a mounting face during electrical connections to an external substrate. In the context herein, the term “external substrate” to which a semiconductor light emitting chip or a semiconductor light emitting device is electrically connected refers to a PCB (Printed Circuit Board), a submount, a TFT (Thin Film Transistor) or the like.

FIG. 2 shows another example of a semiconductor light emitting chip disclosed in U.S. Pat. No. 7,262,436. For convenience of description, similar components may be indicated by the same or different reference numerals and technical terms as appropriate.

The semiconductor light emitting chip includes a growth substrate 21, and a stack of layers sequentially deposited on the growth substrate 21, including a first semiconductor layer 23 having a first conductivity, an active layer 24 adapted to generate light by electron-hole recombination and a second semiconductor layer 25 having a second conductivity different from the first conductivity. Three-layered electrode films 29, 29-1 and 29-2 adapted to reflect light towards the growth substrate 21 are then formed on the second semiconductor layer 25. In particular, a first electrode film 29 can be a reflecting Ag film, a second electrode film 29-1 can be a Ni diffusion barrier, and a third electrode film 29-2 can be an Au bonding film. Further, an electrode 28 serving as a pad is formed on an etched exposed portion of the first semiconductor layer 23. Here, one side of the electrode film 29-2 serves as a mounting face during electrical connections to an external substrate. This particular type of the semiconductor light emitting chip as shown in FIG. 2 is called a flip chip. In this flip chip of FIG. 2, the electrode 28 formed on the first semiconductor layer 23 is placed at a lower height level than the electrode films 29, 29-1, and 29-2 formed on the second semiconductor layer, but alternatively, it may be formed at the same height level as the electrode films. Here, height levels are given with respect to the growth substrate 21.

FIG. 3 shows another example of a semiconductor light emitting chip disclosed in U.S. Pat. No. 8,008,683. For convenience of description, similar components may be indicated by the same or different reference numerals and technical terms as appropriate.

The semiconductor light emitting chip includes a stack of semiconductor layers sequentially deposited on a growth substrate, including a first semiconductor layer 33 having a first conductivity, an active layer 34 for generating light by electron-hole recombination, and a second semiconductor layer 35 having a second conductivity different from the first conductivity; an upper electrode 36 formed on a side free of the growth substrate; a supporting substrate 31 for supporting the semiconductor layers 33, 34 and 35 while supplying current to the second semiconductor layer 35; and a lower electrode 32 formed on the supporting substrate 31. The upper electrode 36 is electrically connected to an external substrate by wire bonding. One side of the lower electrode 32 serves as a mounting face during electrical connections to the external substrate. The semiconductor light emitting device as shown in FIG. 3 corresponds to a vertical chip where the electrodes 36 and 32 are disposed above and below the active layer 34, respectively.

FIG. 4 shows another example of a semiconductor light emitting device in the prior art.

The semiconductor light emitting device 40 has lead frames 41 and 42, a mold 43, and a vertical-type light emitting chip 45 in a cavity 44 which is filled with an encapsulation member 47 containing a wavelength converting material 46. The lower surface of the vertical-type light emitting chip 45 is directly electrically connected to the lead frame 41, and the upper surface 48 thereof is electrically connected to the lead frame 42 by a wire 180. A portion of the light coming out of the vertical-type light emitting chip 45 excites the wavelength converting material 46 such that lights of different colors are generated, and white light is produced by mixing two different lights. For instance, blue light is generated by the semiconductor light emitting chip 45, and yellow light is generated by the wavelength converting material 46 when it is excited. Then these blue and yellow lights can be mixed to produce white light. Alternatively, while the semiconductor light emitting device shown in FIG. 4 includes the vertical-type light emitting chip 45 as shown in FIG. 3, it may also be obtained utilizing the semiconductor light emitting chips as illustrated in FIG. 1 and FIG. 2.

FIG. 5 illustrates an LED display described in Japanese patent application laid-open No. 1995-288341. For convenience of description, similar components may be indicated by the same or different reference numerals and technical terms as appropriate.

FIG. 5 is a top view showing a pixel structure of the LED display. In the pixel structure, semiconductor light emitting chips 54, 55 and 56 are electrically connected to conductor layers 51 formed on the PCB. The semiconductor light emitting chip 54 that emits blue light is a lateral chip, which is electrically connected to the conductor layer 51 by wire bonding and is attached to the conductor layer 51 by the insulating adhesive 53. Meanwhile, the semiconductor light emitting chips 55 and 56 that emit green and red lights, respectively, are vertical chips, which are electrically connected to the conductor layer 51 by wire bonding and by a conductive adhesive 57. These semiconductor light emitting chips are enveloped by a cover member 52, separating them from their neighboring chips. Although not shown, a sealing member may be employed to cover the semiconductor light emitting chips 54, 55 and 56 for protection.

As a compact, light-weight design is a trend nowadays, semiconductor light emitting chips are also being produced in smaller sizes to keep abreast of current technical trends. However, for a semiconductor light emitting chip where mini- or micro-LED chips having a maximum side-length of 300 μm or less are used, for example, pads are also smaller and have a narrower space between them, resulting in the occurrence of shorts or cracks (poor bonding) during the SMT (Surface Mounted Technology) process.

Accordingly, there is a need to produce a semiconductor light emitting device using mini- or micro-LED chips that is adapted to resolve those problems during the SMT process and to be optimized for a transparent display.

The purpose of the disclosure will be described hereinafter.

### SUMMARY

This section provides a general summary of the disclosure and is not a comprehensive disclosure of its full scope or all of its features.

According to one aspect of the present disclosure, there is provided a semiconductor light emitting device, comprising: at least one semiconductor light emitting chip, with each chip including a plurality of electrodes; a plurality of pads arranged at a designated distance from the plurality of electrodes on a plane, respectively; electrical connections provided on the same plane as the plurality of pads for electrically connecting the electrodes and the pads, respectively; and an encapsulation member for covering the at least one semiconductor light emitting chip.

According to another aspect of the present disclosure, there is provided a method for manufacturing a semiconductor light emitting device including at least one semiconductor light emitting chip, the method comprising: preparing a substrate; providing the at least one semiconductor light emitting chip on the substrate; providing an encapsulation member over the substrate and the semiconductor light emitting chips; removing the substrate; and forming, on the encapsulation member, electrical connections between pads and the semiconductor light emitting chips, respectively, with each of the pads being arranged at a designated distance from each of the light emitting chips.

According to another aspect of the present disclosure, there is provided a method for manufacturing a semiconductor light emitting device including at least one semiconductor light emitting chip, the method comprising: preparing a substrate; forming, on the substrate, electrical connections for connecting a plurality of pads and the at least one semiconductor light emitting chip, respectively, with the plurality of pads being arranged at a designated distance from the semiconductor light emitting chips; providing the at least one semiconductor light emitting chip on the substrate; providing an encapsulation member over the substrate and the semiconductor light emitting chips; and removing the substrate.

According to another aspect of the present disclosure, there is provided a semiconductor light emitting device, comprising: a semiconductor light emitting chip including a first electrode and a second electrode; a substrate including a plate on which electrical connections are formed, with the electrical connections including a first electrical connection electrically connected to the first electrode and a second electrical connection electrically connected to the second electrode; and metal blocks provided on the substrate, with the metal blocks including a first metal block that includes an upper surface electrically connected to an external substrate and a lower surface electrically connected to the first electrical connection, and a second metal block that includes an upper surface electrically connected to an external substrate and a lower surface electrically connected to the second electrical connection, wherein the metal blocks have a height equal to or greater than that of the semiconductor light emitting chip.

Objectives, advantages, and a preferred mode of making and using the claimed subject matter may be understood best by reference to the accompanying drawings in conjunction with the following detailed description of illustrative embodiments.

### BRIEF DESCRIPTION OF THE DRAWINGS

FIG. 1 shows an example of a semiconductor light emitting chip in the prior art.

FIG. 2 shows another example of a semiconductor light emitting chip disclosed in U.S. Pat. No. 7,262,436.

FIG. 3 shows another example of a semiconductor light emitting chip disclosed in U.S. Pat. No. 8,008,683.

FIG. 4 shows another example of a semiconductor light emitting device in the prior art.

FIG. 5 illustrates an LED display described in Japanese patent application laid-open No. 1995-288341.

FIG. 6 shows an exemplary embodiment of a semiconductor light emitting device according to the present disclosure.

FIG. 7 shows another exemplary embodiment of a semiconductor light emitting device according to the present disclosure.

FIG. 8 shows other exemplary embodiments of a semiconductor light emitting device according to the present disclosure.

FIG. 9 shows other exemplary embodiments of a semiconductor light emitting device according to the present disclosure.

FIG. 10 is a detailed view of the A part in FIG. 9B.

FIG. 11 illustrates different patterns according to the present disclosure.

FIG. 12 shows an exemplary embodiment of a method for manufacturing a semiconductor light emitting device according to the present disclosure.

FIG. 13 shows another exemplary embodiment of a method for manufacturing a semiconductor light emitting device according to the present disclosure.

FIG. 14 shows Zener diodes according to the present disclosure.

FIG. 15 shows another exemplary embodiment of a semiconductor light emitting device according to the present disclosure.

FIG. 16 shows another exemplary embodiment of a semiconductor light emitting device according to the present disclosure.

FIG. 17 shows another exemplary embodiment of a method for manufacturing a semiconductor light emitting device according to the present disclosure.

FIG. 18 shows another exemplary embodiment of a semiconductor light emitting device according to the present disclosure.

FIG. 19 illustrates applications of a semiconductor light emitting device of the present disclosure to a transparent substrate.

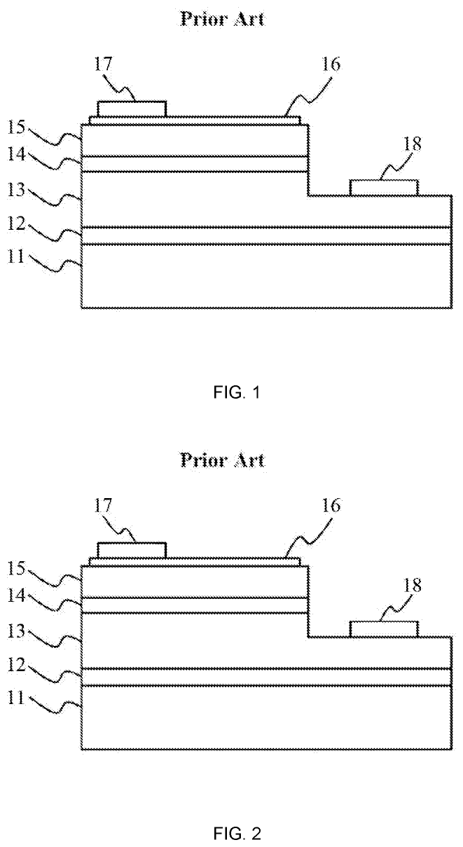

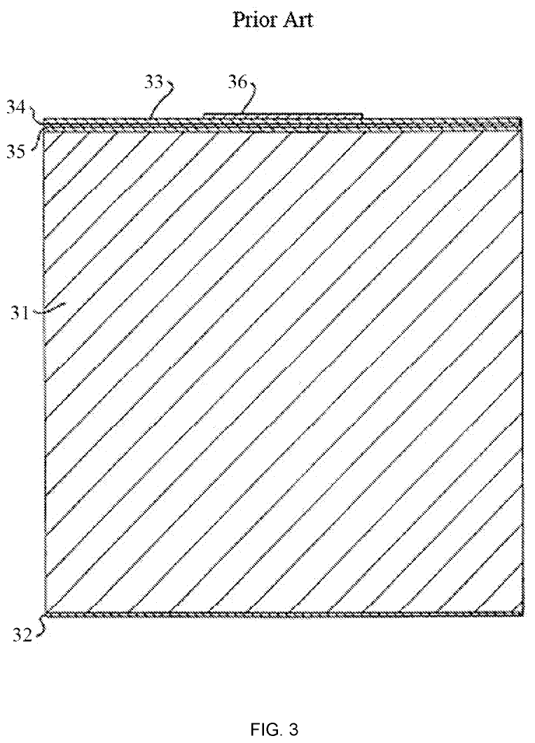

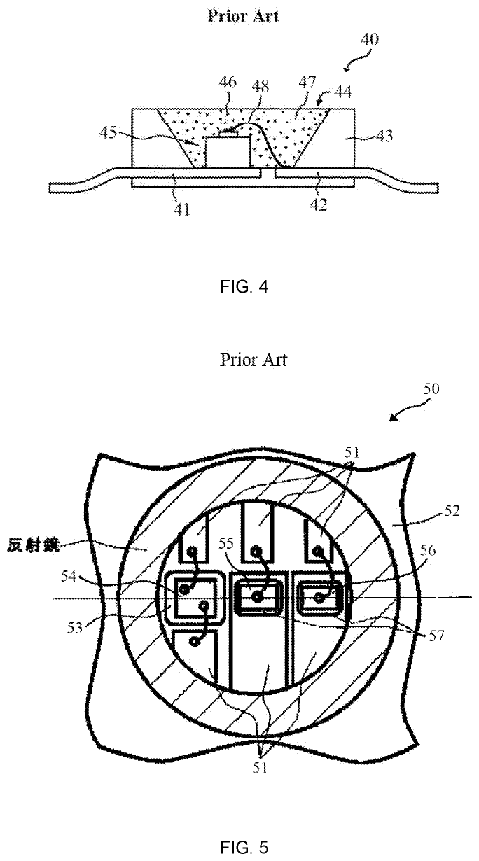

### DETAILED DESCRIPTION

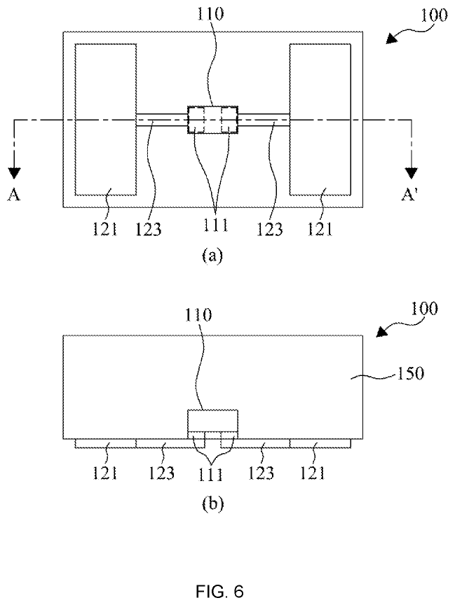

FIG. 6 shows an exemplary embodiment of a semiconductor light emitting device 100 according to the present disclosure.

FIG. 6A is a top view of the semiconductor light emitting device 100, and FIG. 6B is a cross-sectional view taken along with AA′ in FIG. 6A.

The semiconductor light emitting device 100 includes at least one semiconductor light emitting chip 110, a plurality of pads 121, electrical connections 123, and an encapsulation member 150.

Each of the semiconductor light emitting chips 110 includes a plurality of electrodes 111.

The pads 121 are arranged at a designated distance from the semiconductor light emitting chips 110. The semiconductor light emitting device 100 is directly electrically connected to an external substrate through the pads 121.

As mentioned above, the pads 121 are not located beneath the semiconductor light emitting chips 110. Rather, there is a designated distance between the pads 121 and the semiconductor light emitting chips 110. With such space created, bigger pads 121 may be used and the pads 121 may be spaced with a broader distance between them, preventing the occurrence of shorts and cracks (poor bonding) during the SMT process. When this is applied to a transparent display where some elements (e.g., pads 121 and semiconductor light emitting chips 110) of the semiconductor light emitting device 100 are not clustered but are scattered, occupying a certain area, the semiconductor light emitting device 100 may become less visible. In addition, as the light can travel through the space between the pads 121 and the semiconductor light emitting chips 110, six-sided light emission can be accomplished. Here, the pads 121 are arranged in a one-to-one correspondence with the electrodes 111.

The electrical connections 123 are provided between the pads 121 and the electrodes 111, such that the pads 121 and the electrodes 111 are electrically connected to each other. In particular, the electrical connections 123 may be formed on the same plane as the pads 121.

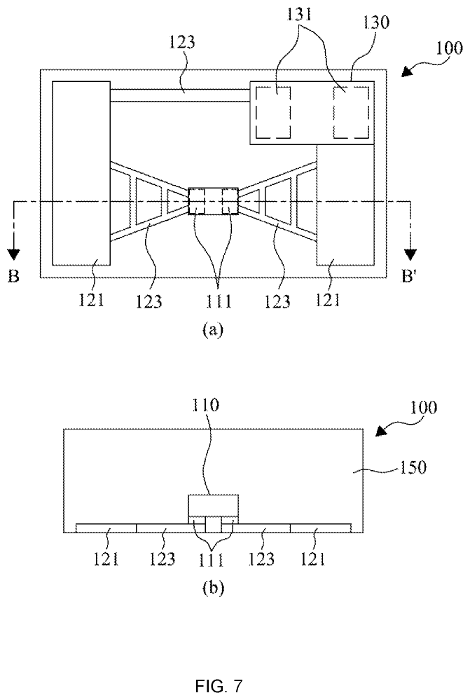

In the example shown in FIG. 6A, the electrical connection 123 is formed of a single line. In this case, if the electrical connection 123 is cut off, the semiconductor light emitting chip 110 will stop working. A possible solution for this will be described later with reference to FIG. 7.

The encapsulation member 150 serves to cover the semiconductor light emitting chips 110. Typically, it is made of a light-transmitting material. This encapsulation member 150, being spaced from the semiconductor light emitting chips 110 and the pads 121 by a designated distance, may contribute to a semiconductor light emitting device featuring six-sided light emission. In an alternative example, the pads 121 and the electrical connections 123 may be projected out of the encapsulation member 150. FIG. 7 illustrates an example where the pads 121 and the electrical connections 123 are formed in the encapsulation member 150.

Preferably, the size of the pad 121 is larger than the size of the semiconductor light emitting chip 110, and the designated distance between the pad 121 and the semiconductor light emitting chip 110 is greater than the size of the semiconductor light emitting chip 110. For example, if the semiconductor light emitting chip 110 is a mini- or micro-semiconductor light emitting chip having a maximum side length of 300 μm or less, and the pad 121 has a maximum side length of at least 100 μm, the distance between one pad 121 and one semiconductor light emitting chip 110 should be at least 150 μm. The resulting semiconductor light emitting device 100 will have a maximum side length of 300 μm or more.

FIG. 7 shows another exemplary embodiment of a semiconductor light emitting device 100 according to the present disclosure.

FIG. 7A is a top view of the semiconductor light emitting device 100, and FIG. 7B is a cross-sectional view of the semiconductor light emitting device 100 shown in FIG. 7A.

The electrical connections 123 form multiple paths between each of the pads 121 and each of the electrodes 111. Since the pads 121 and the electrodes 111 are electrically connected through these multiple paths, even if one of the paths may be cut off, the pads 121 would remain electrically connected to the electrodes 111 with the help of the other paths. Meanwhile, if the pads and the semiconductor light emitting chips are electrically connected by one single line as in FIG. 6A, failure in the line would inevitably cause the semiconductor light emitting device to stop working, as discussed earlier. Thus, the presence of multiple paths ensures that the pads 121 and the electrodes 111 always stay electrically connected to each other through one of the paths, even if one line might have been cut off. Moreover, the electrical connections 123 are not clustered and but are spread out broadly and thinly, making the back side of the semiconductor light emitting device 100 more visible.

The encapsulation member 150 is adapted to cover the electrical connections 123, with at least a portion of the electrical connections 123 being exposed. Similarly, the encapsulation member 150 is adapted to cover the pads 121, with at least a portion of the pads 121 being exposed.

As shown, a Zener diode 130 is provided to prevent the application of a reverse voltage across the semiconductor light emitting chips 110. The Zener diode 130 and the semiconductor light emitting chips 110 are connected in parallel, such that the Zener diode 130 ensures that a current keeps flowing through the chips 110 and the chips 110 are protected even if a reverse voltage is applied thereto.

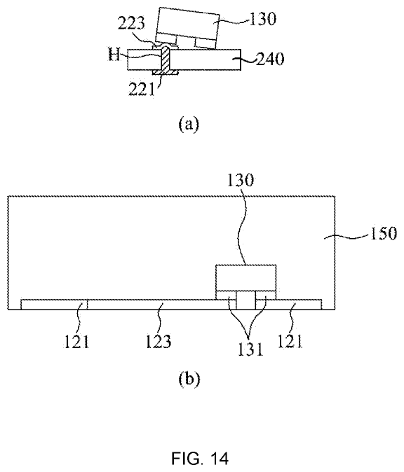

The Zener diode 130 includes a plurality of Zener electrodes 131; one Zener electrode 131 is in contact with a corresponding pad 121, and another Zener electrode 131 is electrically connected in reverse parallel to the semiconductor light emitting chips 110. In other words, one Zener electrode 131 out of the plurality of Zener electrodes 131 may be connected to one of the electrodes 111 of the semiconductor light emitting chip 110, and to one of the pads 121, or to the electrical connection 123. The Zener diode 130 will be described in more details with reference to FIG. 14 below.

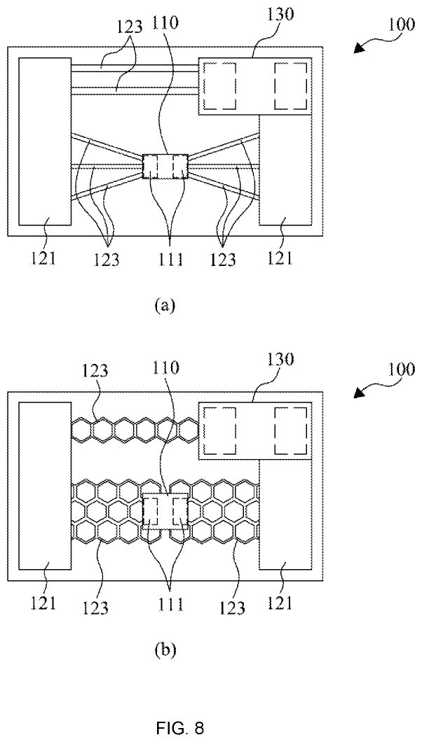

FIG. 8 shows other exemplary embodiments of a semiconductor light emitting device according to the present disclosure.

FIG. 8A illustrates the electrical connections 123 in the form of multiple paths between the pads 121 and the electrodes 111.

FIG. 8B illustrates the electrical connections in the form of a net of the hexagonal honeycomb pattern. The pattern has a uniform size. This net form makes the back side of the semiconductor light emitting device 100 more visible.

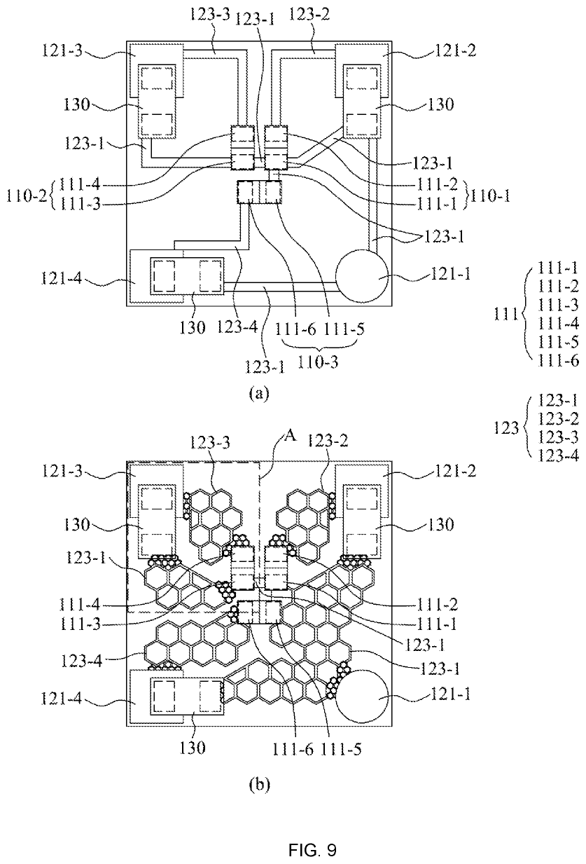

FIG. 9 shows other exemplary embodiments of a semiconductor light emitting device according to the present disclosure.

In particular, FIG. 9A illustrates a semiconductor light emitting device 100 including a plurality of semiconductor light emitting chips 110, a plurality of pads 121 and electrical connections 123 according to the present disclosure.

The plurality of semiconductor light emitting chips 110 may be comprised of a first semiconductor light emitting chip 110 including a first electrode 111-1 and a second electrode 111-2, a second semiconductor light emitting chip 110 including a third electrode 111-3 and a fourth electrode 111-4, and a third semiconductor light emitting chip 110 including a fifth electrode 111-5 and a sixth electrode 111-6. The first electrode 111-1 and the second electrode 111-2 of the first semiconductor light emitting chip 110 have different polarities. For example, in the first semiconductor light emitting chip 110, the first electrode 111-1 may be a negative (−) electrode, while the second electrode 111-1 may be a positive (+) electrode. Similarly, in the second semiconductor light emitting chip 110, the third electrode 111-3 may be a negative (−) electrode, while the fourth electrode 111-4 may be a positive (+) electrode. Also, in the third electrode 110, the fifth electrode 111-5 may be a negative (−) electrode, while the sixth electrode 111-6 may be a positive (+) electrode.

The plurality of pads 121 may be comprised of a first pad 121-1, a second pad 121-2, a third pad 121-3, and a fourth pad 121-4. The first pad 121-1 is electrically connected to the first electrode 111-1, the third electrode 111-3, and the fifth electrode 111-5. The second pad 121-2 is electrically connected to the second electrode 111-2. The third pad 121-3 is connected to the fourth electrode 111-4. The fourth pad 121-4 is connected to the sixth electrode 111-6. In an alternative example, the first pad 121-1, the second pad 121-2, the third pad 121-3, and the fourth pad 121-4 may have different polarities. In another alternative example, while the second pad 121-2, the third pad 121-3, and the fourth pad 121-4 may have the same polarity, they are arranged separately to control ON/OFF of the first semiconductor light emitting chip 110, the second semiconductor light emitting chip 110 and the third semiconductor light emitting chip 110, respectively.

The electrical connections 123 may be comprised of first electrical connections 123-1, a second electrical connections 123-2, a third electrical connection 123-3, and a fourth electrical connection 123-4. The first electrical connections 123-1 serve to electrically connect the first pad 121-2 and the first electrode 111-1, third electrode 111-3, and fifth electrode 111-5. The second electrical connection 123-2 serves to electrically connect the second pad 121-2 and the second electrode 111-2. The third electrical connection 123-3 serves to electrically connect the third pad 121-3 and the fourth electrode 111-4. The fourth electrical connection 123-4 serves to electrically connect the fourth pad 121-4 and the sixth electrode 111-6.

The plurality of semiconductor light emitting chips 110 may be turned ON/OFF in various combinations to emit lights, such as white light or lights of different colors. The semiconductor light emitting chips 110 are centered in the semiconductor light emitting device 100, and each of the semiconductor light emitting chip 110 (110-1, 110-2, and 110-3) and each of the pads 121 (121-1, 121-2, and 121-3) are separated by a designated distance from each other.

As colors are mixed to form a color pixel, the semiconductor light emitting chips 110 are needed to be at the center of the semiconductor light emitting device 100. However, if the pads 121 are arranged beneath or right under the chips 110, any neighboring pads 121 may undergo a short during the SMT process. Therefore, providing electrical connections 123 between the pads 121 and the semiconductor light emitting chips 111 as in the present disclosure may benefit from these centrally arranged mini- or micro- semiconductor light emitting chips 110.

FIG. 9B illustrates another semiconductor light emitting device 100 including a plurality of semiconductor light emitting chips 110 according to the present disclosure.

In this example, the electrical connections 123 are provided in the net structure, in order to prevent any possible disconnection when the electrical connections 123 are formed of one single line as mentioned in FIG. 6A. Here, the electrical connections 123 are thinner and are spread across a broader area. Also, the electrical connections 123 form multiple paths between the pads 121 and the electrodes 111 as in FIG. 7, such that even if a part of the thin electrical connection 123 may be cut off, it is highly possible that the pads 121 and the electrodes 111 would remain connected. In other words, it is very unlikely to cause the semiconductor light emitting chips 110 to be electrically disconnected.

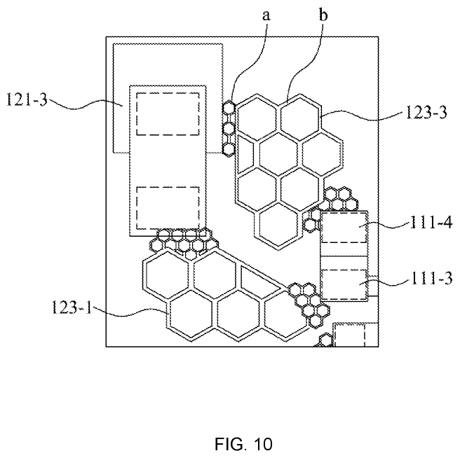

The electrical connections 123 may have a certain pattern, e.g., a net structure. The electrical connections 123 in contact with the pads 121 or the electrodes 111 are smaller than the electrical connections 123 not in contact with the pads 121 or the electrodes 111. This will be described in further details with reference to FIG. 10 below.

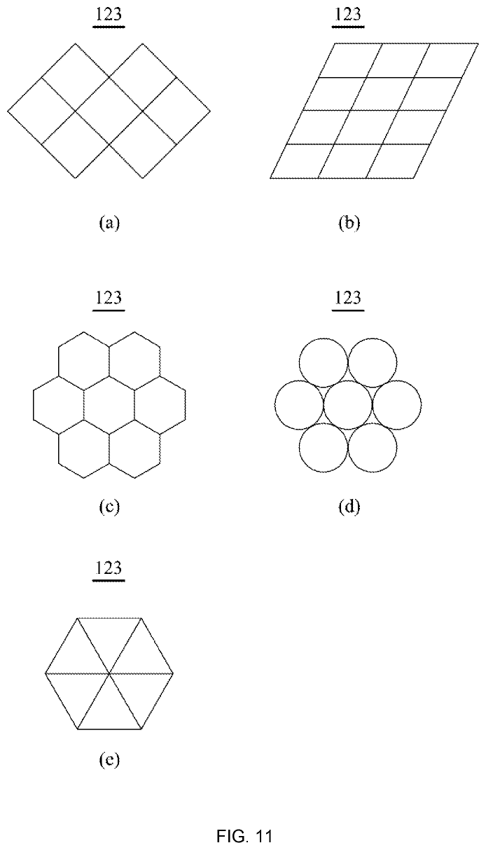

The first through fourth electrical connection 123-1-123-4 are formed in a net structure by connecting a plurality of patterns together. The pattern may have a polygonal shape. Examples of such a polygonal shape will be provided later with reference to FIG. 11. The first through fourth electrical connections 123-1-123-4 in the net structure is advantageous especially when the semiconductor light emitting device 100 is used for a transparent display in that the electrical connections 123 in the form of thinner lines across a broader area than those in FIG. 9A make the back side of the semiconductor light emitting device 100 of FIG. 9B more visible than the back side of the semiconductor light emitting device 100 of FIG. 9A.

FIG. 10 is a detailed view of the A part in FIG. 9B.

The third electrical connection 123-3 is positioned between the third pad 121-3 and the fourth electrode 111-4. As shown, the third electrical connection 123-3 has a smaller pattern portion closer towards or in contact with the third pad 121-3 and the fourth electrode 111-4 such that more paths may be formed. That is, because the third electrical connection 123-3 has a limited area that gets closer and comes in contact with the third pad 121-3 and the fourth electrode 111-4, the size of the pattern (a) which actually comes in contact with the third pad 121-3 and the fourth electrode 111-4 is made larger than the size of the pattern (b) which is not in contact with the third pad 121-3 and the fourth electrode 111-4. As compared with the electrical connection of a one-sized pattern, multiple paths can be created for the third electrical connection 123-3 between the third pad 121-3 and the fourth electrode 111-4, with a substantially lower probability of disconnection (being cut off).

FIG. 11 illustrates different patterns according to the present disclosure.

The pattern may have various polygonal shapes including, but are not limited thereto, tetragonal (see FIG. 11A-B), hexagonal (see FIG. 11C), circular (see FIG. 11D), and triangular (see FIG. 11E) shapes.

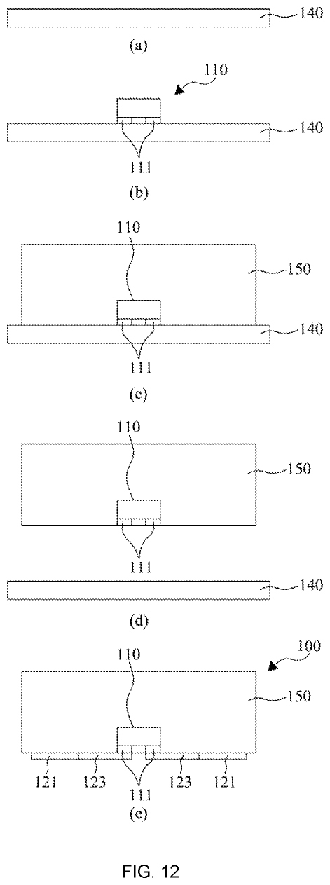

FIG. 12 shows an exemplary embodiment of a method for manufacturing a semiconductor light emitting device according to the present disclosure.

In the method for manufacturing a semiconductor light emitting device including at least one semiconductor light emitting chip 110, first of all, a substrate 140 is prepared as shown in FIG. 12A. The substrate 140 may be a silicone tape, for example, onto which the semiconductor light emitting chips 110 are temporarily attached later. The substrate 140 is not electrically connected to the semiconductor light emitting chips 110.

Referring next to FIG. 12B, the at least one semiconductor light emitting chip 110 are provided on the substrate 140. Although not shown, Zener diodes 130 (see FIG. 7) may be provided on the substrate 140. If present, the Zener diodes 130 are arranged corresponding to the semiconductor light emitting chips 110, while keeping a designated distance between the Zener diodes 130 and the chips 110.

After that, the encapsulation member 150 is provided over the substrate 140 and semiconductor light emitting chips 110, as shown in FIG. 12C. The encapsulation member 150 covers the substrate 140, and the semiconductor light emitting chips 110 are secured accordingly.

The substrate 140 is then removed as shown in FIG. 12D. The substrate 140 t may be removed because it was originally provided for temporary attachment of the semiconductor light emitting chips 110.

Referring finally to FIG. 12E, a plurality of pads 121 and electrical connections 123 are formed under the encapsulation member 150. In particular, the pads 121 are arranged at a designated distance from the at least one semiconductor light emitting chip 110, and the electrical connections 123 are arranged between the pads 121 and the semiconductor light emitting chips 110 for electrically connecting them. As can be seen, the formation of the pads 121 and electrical connections 123 comes after the encapsulation member 150 is formed, such that the pads 121 and the electrical connections 123 may be projected out of the encapsulation member 150. For example, the pads 121 and the electrical connections 123 are deposited on the same plane, i.e., one side of the encapsulation member 150.

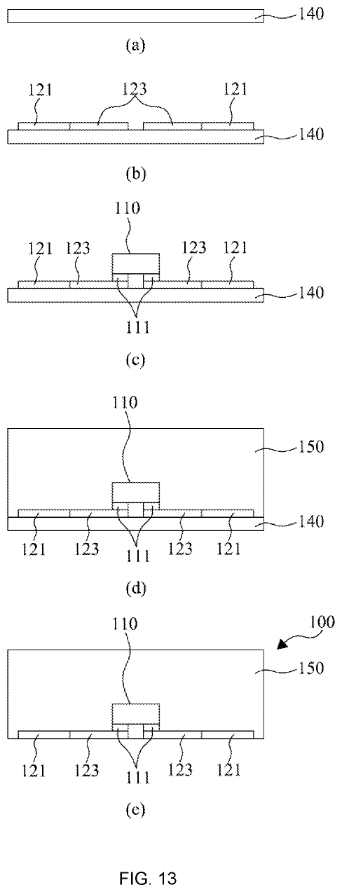

FIG. 13 shows another exemplary embodiment of a method for manufacturing a semiconductor light emitting device according to the present disclosure.

In the method for manufacturing a semiconductor light emitting device including at least one semiconductor light emitting chip 110, first of all, a substrate 140 is prepared as shown in FIG. 13A. The substrate 140 may be a silicone tape, for example, onto which the semiconductor light emitting chips 110 are temporarily attached later. The substrate 140 is not electrically connected to the semiconductor light emitting chips 110.

Referring next to FIG. 13B, on the substrate 140, there are formed a plurality of pads 121 at a designated distance from at least one semiconductor light emitting chip 110 (to be described later), and electrical connections 123 for electrically connecting the pads 121 and the semiconductor light emitting chips 110. For example, the pads 121 and the electrical connections 123 are deposited on the same plane, i.e., one side of the encapsulation member 150.

Following that, at least one semiconductor light emitting chip 110 is provided on the substrate 140, as shown in FIG. 13C. In particular, these semiconductor light emitting chips 110 are positioned to be in contact with the electrical connections 123. Although not shown, Zener diodes 130 may be provided on the pads 121, in a one-to-one correspondence with the semiconductor light emitting chips 110.

The encapsulation member 150 is then provided over the substrate 140 and the semiconductor light emitting chips 110, as shown in FIG. 13D.

Finally, the substrate 140 is removed, as shown in FIG. 13E. As the pads 121 and the electrical connections 123 are formed and covered with the encapsulation member 150 afterwards, the pads 121 as well as the electrical connections 123 are positioned inside the encapsulation member 150. Thus, when the substrate 140 is removed, only the sides of the pads 121 and electrical connections 123 that were in contact with the substrate 140 are exposed.

If the pads 121 and the electrical connections 123 are projected out of the encapsulation member 150 as shown in FIG. 12E, adhesion between the encapsulation member 150 and the pads 121/electrical connections 123 gets weaker and separated from each other. Therefore, it is preferred that the pads 121 and the electrical connections 123 remain inside the encapsulation member 150.

FIG. 14 shows Zener diodes according to the present disclosure.

FIG. 14A illustrates how a Zener diode is mounted in a semiconductor light emitting device in the art.

A hole (H) is formed in the PCB substrate 240, a pad 221 is provided under the PCB substrate 240, and an electrical connection is formed along the hole (H) until it sticks out from the upper surface of the PCB substrate 240. In addition, a pad electrode 223 is formed on the PCB substrate 240 such that it is connected to the pad 221. With the electrical connection being projected, the pad electrode 223 is also projected. Therefore, a gap is created when the Zener electrodes 131 of the Zener diode 130 are attached to the pad electrode 223, which will likely cause the Zener diode 130 to easily come off. Therefore, in an alternative example, although not shown, the Zener diode 130 may be provided in an area other than the pad electrode 223, avoiding the hole (H) and without being overlapped with the pad 221.

FIG. 14B is a cross-sectional view taken along line BB′ of FIG. 7.

As shown, one of the Zener electrodes 131 of the Zener diode 130 is in contact with a pad 121. This structure is possible because the pad 121 is formed flat, without having the hole (H) (see FIG. 14A) and the pad electrode 223 (see FIG. 14A).

While the pad 121 and the Zener diode 130 are configured to be able to increase the optical loss, it can be overcome by using the flat pad 121 and placing the Zener diode 130 in the pad such that the area of the pad 121 overlaps with the area of the Zener diode 130. For the application to a transparent display, if the pad 121 and the Zener diode 130 are overlapped to a great extent, the semiconductor light emitting device 100 would have a higher transparency.

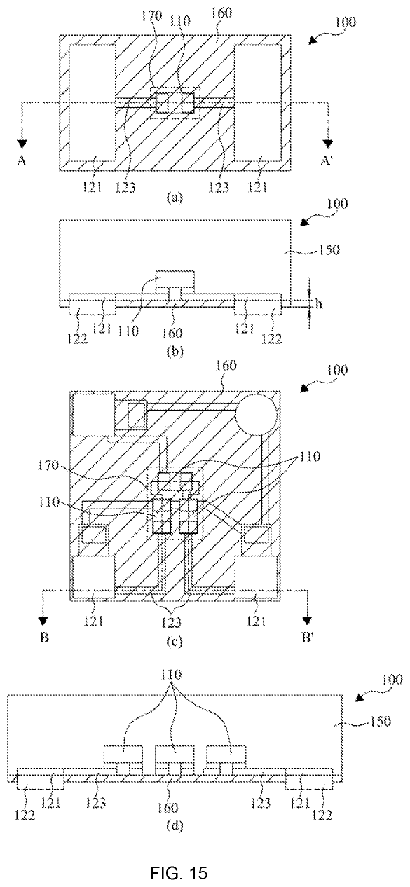

FIG. 15 shows another exemplary embodiment of a semiconductor light emitting device 100 according to the present disclosure.

In particular, FIG. 15A is a bottom view showing the lower surface of the semiconductor light emitting device 100 including a semiconductor light emitting chip 110, and FIG. 15B is a cross-sectional view taken along line AA′ of FIG. 15A.

The semiconductor light emitting device 100 may include an insulating layer 160 adapted to cover the electrical connections 123 and to expose the pads 121. Because the electrical connections 123 are covered with the insulating layer, the occurrence of shorts during soldering can be greatly reduced. The insulating layer can be used regardless that the electrical connections 123 and the pads 121 are arranged inside or projected out of the encapsulation member 150. In general, the insulating layer 160 may be formed by silk screen printing, following the step FIG. 12E or FIG. 13E.

Preferably, the insulating layer 160 has a height (h) of 10 μm or less. As the insulating layer 160 is formed after the step in FIG. 12E or FIG. 13E is completed, exposing the pads 121 are formed, it is disposed at a higher level than the pads 121. Forming the insulating layer 160 at the height (h) of 10 μm or less allows a solder material to make better contact with the pads 121 during soldering for electrical connection to an external substrate. In an alternative example, after the insulating layer 160 is formed, the pads 121 may be subject to a plating process such that the height of the pad 121 may reach a dotted line 122 (FIG. 15B) until it is equal to or greater than the height (h) of the insulating layer 160.

The insulating layer 160 may be made from at least one of transparent materials or opaque materials. For example, if the insulating layer 160 is made from a transparent material, the semiconductor light emitting device 100 thus manufactured will be able to emit lights from six sides. Meanwhile, if the insulating layer 160 is made from an opaque material, the semiconductor light emitting device 100 will be able to emit lights from five sides. If applied to a transparent display, the semiconductor light emitting device 100 often should not let the light escape through its back side. In this case, the insulating layer 160 is preferably made from an opaque material. On the other hands, if the semiconductor light emitting device has dimensions of 500 μm×500 μm or less, it is not much visible even if the insulating layer is made opaque. In the present disclosure, however, the semiconductor light emitting device 100 has larger dimensions (e.g., 1500 μm×1500 μm) than those in the art because of the spacing between the pads and the semiconductor light emitting chips, which makes the semiconductor light emitting device 100 still visible. This can be overcome by employing both transparent and opaque materials for the insulating layer 160. That is, a portion 170 of the insulating layer 160 below the semiconductor light emitting chip 110, indicated by dotted lines in FIG. 15A, is made from an opaque material, while the remaining portion is made from a transparent material. In this way, the light from the semiconductor light emitting chip 110 is prevented from escaping through under the semiconductor light emitting device 100, which ensures that the semiconductor light emitting device 100 having larger dimensions according to the present disclosure may still be suitable for use in a transparent display where the escape of light through under the device is not allowed. The portion 170 indicated by dotted lines is preferably 300 μm or less.

FIG. 15C is a bottom view showing the lower surface of the semiconductor light emitting device 100 including at least one semiconductor light emitting chip 110, for example. FIG. 15D is a cross-sectional view taken along line BB′ of FIG. 15C.

The descriptions in relation to FIG. 15A and FIG. 15B may be applied equally to FIG. 15C and FIG. 15D.

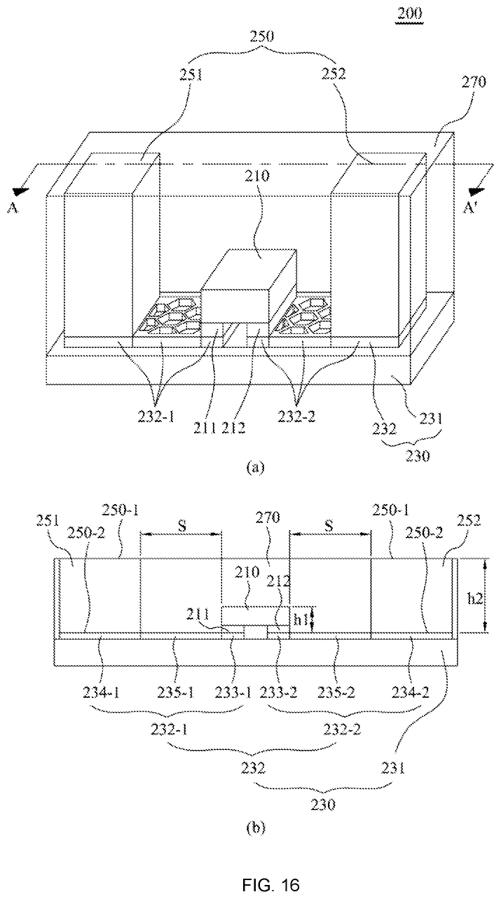

FIG. 16 shows another exemplary embodiment of a semiconductor light emitting device 200 according to the present disclosure.

The semiconductor light emitting device 200 includes a semiconductor light emitting chip 210, a substrate 230, metal blocks 250, and an encapsulation member 270.

The semiconductor light emitting chip 210, which emits light, has dimensions of 300 μm or less (in case of mini-LEDs) or 100 μm or less (in case of micro-LEDs). Both mini-LEDs and micro-LEDs are suitable for the semiconductor light emitting chip 210 in the present disclosure. In an alternative example, the semiconductor light emitting chip 210 may be a flip chip in which the escape of light mainly occurs through the upper surface of the flip chip.

The substrate 230 includes a plate 231 and electrical connections 232. The plate 231 may be made from a light-transmitting material. For example, the plate 231 may be made from glass, sapphire, or the like. The electrical connections 232 may be deposited on the plate 231. The electrical connections 232 serve to electrically connect the semiconductor light emitting chip 210 and the metal blocks 250.

In case of the semiconductor light emitting devices 100 described above beginning from FIG. 6 to FIG. 15, the encapsulation member 150 is in direct contact with the electrical connections 123. When the semiconductor light emitting device 100 is soldered to an external substrate, the encapsulation member 150 and the electrical connections 123 can experience precision deterioration due to heat during the soldering process. The encapsulation member 150 and the electrical connections 123 have substantially different degrees of expansion and contraction, and the electrical connections 123 made thinner according to the present disclosure may even be cut off. This can be overcome by providing the electrical connections 232 on the plate 231 as the plate 231 is resistant to heat-induced deformation. This leads to a simplified manufacturing process and improved reliability overall.

The metal blocks 250 are provided on the substrate 230. The metal blocks 250 are electrically connected to an external substrate. Each metal block 250 has an upper surface 250-1 in contact with an external substrate, and a lower surface 250-2 in contact with the electrical connections 232. The metal blocks 250 may have a column shape, including, but are not limited to, a cylinder, a rectangular cylinder, or the like. In particular, the metal blocks 250 may take any shape, provided that a portion of each of the metal blocks 250 is exposed for electrical connection to an external substrate.

Each metal block 250 may have a height (h2) equal to or greater than the height (h1) of the semiconductor light emitting chip 210. If the height (h2) of the metal blocks 250 is greater than the height (h1) of the semiconductor light emitting chip 210, it enables the semiconductor light emitting device 200 to be electrically connected above the upper surface of the semiconductor light emitting chip 210. Meanwhile, if the height (h2) of the metal blocks 250 is equal to the height (h1) of the semiconductor light emitting chip 210, the upper surface (not shown) of the semiconductor light emitting chip 210 will be exposed, similar to the upper surfaces 250-1 of the metal blocks 250 being exposed. This impedes the complete protection of the semiconductor light emitting chip 210 from outside because the exposed upper surface of the chip 210 will be affected adversely by external physical impacts and electrostatic discharge (ESD) and even discolored due to moisture penetration. Therefore, it is desired that the height (h2) of the metal blocks 250 should be greater than the height (h1) of the semiconductor light emitting chip 210.

The encapsulation member 270 covers the semiconductor light emitting chip 210 and the substrate 230 and encloses the metal blocks 250 in such a manner that the upper surfaces 250-1 of the metal blocks 250 are exposed. The encapsulation member 270 may shrink during curing. Thus, the plate 231 of the substrate 230 is preferably made from a material that is less susceptible to warpage than the silicone tape because if the substrate 230 is bent by the shrinkage force from the encapsulation member 270, the semiconductor light emitting device 200 might as well be broken or bent.

The semiconductor light emitting chip 210 includes a first electrode 211 and a second electrode 212.

The electrical connections 232 is comprised of a first electrical connection 232-1 and a second electrical connection 232-2. The first electrical connection 232-1 is electrically connected to the first electrode 211 of the semiconductor light emitting chip 210, and the second electrical connection 232-2 is electrically connected to the second electrode 212 of the semiconductor light emitting chip 210.

The metal blocks 250 is comprised of a first metal block 251 and a second metal block 252. The first metal block 251 is electrically connected to the first electrical connection 232-1, and the second metal block 252 is electrically connected to the second electrical connection 232-2. The first metal block 251 and the second metal block 252 may have the same height (h2).

The first electrical connection 232-1 includes a first contact portion 233-1, a first pad 234-1, and a first connection portion 235-1.

The first contact portion 233-1 is in contact with the first electrode 211 of the semiconductor light emitting chip 210, and the first pad 234-1 is in contact with the first metal block 251.

The first connection portion 235-1 is provided between the first contact portion 233-1 and the first pad 234-1 to electrically connect the first contact portion 233-1 and the first pad 234-1. Preferably, the first contact portion 233-1 and the first pad 234-1 are arranged at a designated distance from each other. This is particularly important to allow the light to travel towards the lower surface of the semiconductor light emitting chip 210 for six-sided light emission, as it will be difficult for the light to keep going towards the lower surface of the semiconductor light emitting chip 210 if there is no space between the first contact portion 233-1 and the first pad 234-1. In relation with that, the first connection portion 235-1 may have diverse patterns as illustrated in FIG. 11.

The second electrical connection 232-2 includes a second contact portion 233-2, a second pad 234-2, and a second connection portion 235-2.

The second contact portion 233-2 is in contact with the second electrode 212 of the semiconductor light emitting chip 210, and the second pad 234-2 is in contact with the second metal block 252.

The second connection portion 235-2 is provided between the second contact portion 233-2 and the second pad 234-2 to electrically connect the second contact portion 233-2 and the second pad 234-2. Preferably, the second contact portion 233-2 and the second pad 234-2 are arranged at a designated distance from each other. This is particularly important to allow the light to travel towards the lower surface of the semiconductor light emitting chip 210 for six-sided light emission, as it will be difficult for the light to keep going towards the lower surface of the semiconductor light emitting chip 210 if there is no space between the second contact portion 233-2 and the second pad 234-2. In relation with that, the second connection portion 235-2 may have diverse patterns as illustrated in FIG. 11.

The first electrical connection 232-1 may have multiple paths between the first electrode 211 and the first metal block 251, and the second electrical connection 232-2 may have multiple paths between the second electrode 212 and the second metal block 252. In other words, the first contact portion 232-1 and the first pad 234-1 are connected by multiple paths of the first connection portion 232-1, and the second contact portion 233-2 and the second pad 234-2 are connected by multiple paths of the second connection portion 232-2. In addition, the first connection portion 232-1 and the second connection portion 232-2 may create a space which the light can travel through.

Further, the first pad 234-1 and the second pad 234-2 may serve as passages electrically connected to an external substrate, while retaining the same features as the pads 121 illustrated in FIG. 6.

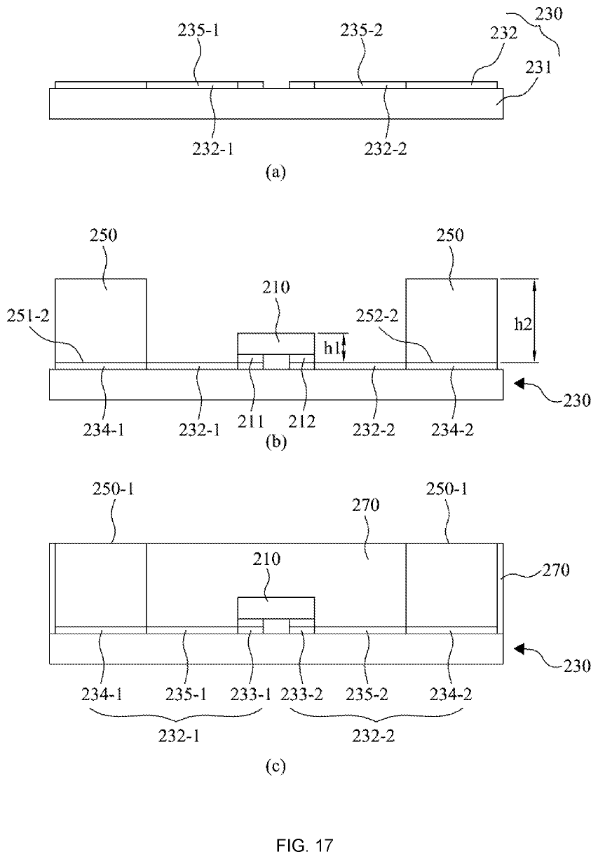

FIG. 17 shows another exemplary embodiment of a method for manufacturing a semiconductor light emitting device according to the present disclosure

First of all, the substrate 230 is prepared as shown in FIG. 17A. The substrate 230 is obtained by preparing the plate 231, followed by forming the electrical connections 232 on the plate 231 by deposition, for example. The electrical connections 232 may be comprised of the first electrical connection 232-1 and the second electrical connection 232-2.

Referring next to FIG. 17B, the semiconductor light emitting chip 210 and the metal blocks 250 are provided on the substrate 230. The semiconductor light emitting chip 210 includes a first electrode 211 and a second electrode 212. The first electrode 211 is electrically connected to the first electrical connection 232-1, and the second electrode 212 is electrically connected to the second electrical connection 232-2.

The lower surfaces 251-2 and 252-2 of the first metal block 251 and the second metal block 252 may have areas in any dimensions, provided that the first pad 234-1 is electrically connected to the first metal block 251, and that and the second pad 234-2 is electrically connected to the second metal block 252.

Referring lastly to FIG. 17C, the encapsulation member 270 are provided to enclose the first metal block 251 and the second metal block 252, except for the upper surfaces 251-1 and 252-1 of the first and second metal blocks 251 and 252. In addition, the encapsulation member 270 covers the upper surfaces of the semiconductor light emitting chip 210 and substrate 230.

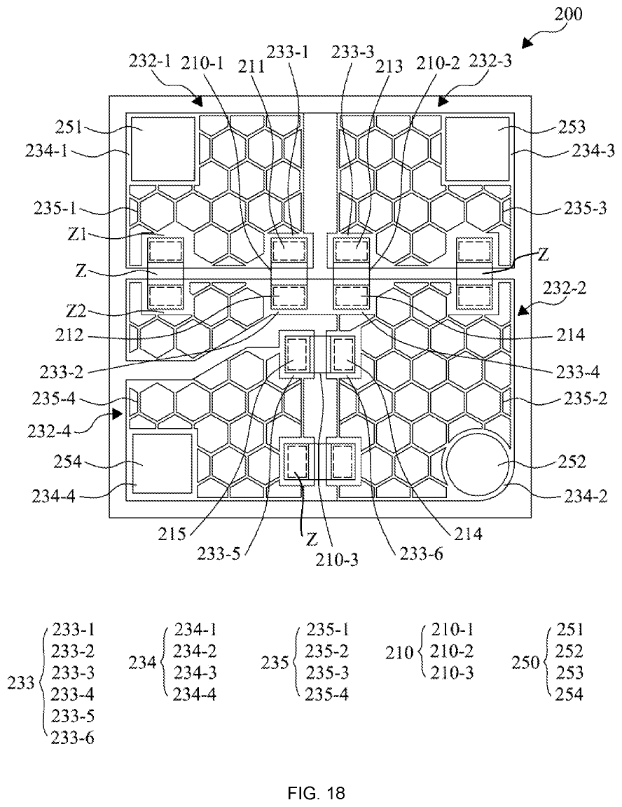

FIG. 18 shows another exemplary embodiment of a semiconductor light emitting device 200 according to the present disclosure.

The semiconductor light emitting device 200 includes a plurality of semiconductor light emitting chips 210. The plurality of semiconductor light emitting chips 210 may emit red light, green light, and blue light, respectively. The plurality of semiconductor light emitting chips 210 may be comprised of a first semiconductor light emitting chip 210-1, a second semiconductor light emitting chip 210-2, and a third semiconductor light emitting chip 210-3. The first semiconductor light emitting chip 210-1 includes a first electrode 211 and a second electrode 212, the second semiconductor light emitting chip 210-2 includes a third electrode 213 and a fourth electrode 214, and the third semiconductor light emitting chip 210-3 includes a fifth electrode 215 and a sixth electrode 216.

The metal blocks 250 may be comprised of a first metal block 251, a second metal block 252, a third metal block 253, and a fourth metal block 254. These metal blocks may have different polarities: the first metal block 251 may have a polarity different from the second metal block 252 and from the third and fourth metal blocks 253 and 254. Four metal blocks 250 are provided in order to control the first semiconductor light emitting chip 210-1, the second semiconductor light emitting chip 210-2, and the third semiconductor light emitting chip 210-3, respectively. For instance, the second metal block 252 may be used as a common electrode.

The electrical connections 232 (FIG. 16) may be comprised of a first electrical connection 232-1, a second electrical connection 232-2, a third electrical connection 232-3, and a fourth electrical connection 232-4.

The first electrical connection 232-1 may include a first contact portion 233-1, a first pad 234-1, and a first connection portion 235-1. The second electrical connection 232-1 may include a second contact portion 233-2, a fourth contact portion 233-4, a sixth contact portion 233-6, a second pad 234-2, and a second connection portion 235-2. The third electrical connection 232-3 may include a third contact portion 233-3, a third pad 234-3, and a third connection portion 235-3. The fourth electrical connection 232-4 may include a fourth contact portion 233-4, a fourth pad 234-4, and a fourth connection portion 235-4.

The first contact portion 233-1 is in contact with the first electrode 211 and they are electrically connected to each other. The second contact portion 233-2 is in contact with the second electrode 212 and they are electrically connected to each other. The third contact portion 233-3 is in contact with the third electrode 213 and they are electrically connected to each other. The fourth contact portion 233-4 is in contact with the fourth electrode 214 and they are electrically connected to each other. The fifth contact portion 233-5 is in contact with the fifth electrode 215 and they are electrically connected to each other. The sixth contact portion 233-6 is in contact with the sixth electrode 216 and they are electrically connected to each other.

Likewise, the first pad 234-1 is in contact with the first metal block 251 and they are electrically connected to each other. The second pad 234-2 is in contact with the second metal block 252 and they are electrically connected to each other. The third pad 234-3 is in contact with the third metal block 253 and they are electrically connected to each other. The fourth pad 234-4 is in contact with the fourth metal block 254 and they are electrically connected to each other.

The first connection portion 235-1 is provided between the first pad 234-1 and the first contact portion 233-1 to electrically connect them. The second connection portion 235-2 is provided between the second pad 234-2 and the second, fourth and sixth contact portions 233-2, 234-4 and 233-6, respectively, to electrically connect them. The third connection portion 235-3 is provided between the third pad 234-3 and the third contact portion 233-3 to electrically connect them. The fourth connection portion 235-4 is provided between the fourth pad 234-4 and the fifth contact portion 233-4 to electrically connect them.

The semiconductor light emitting device 200 may further include a Zener diode z. The Zener diode z has been described in detail with reference to FIG. 7. The Zener diode z may be electrically connected to the first and second electrical connections 232-1 and 232-2. In relation with this, the first electrical connection 232-1 and the second electrical connection 232-2 may have Zener pads z1 and z2, respectively, that come in contact with the Zener diode z. Although not shown, other Zener diodes z may be provided between the third electrical connection 232-3 and the second electrical connection 232-3, and between the fourth electrical connection 232-4 and the second electrical connection 232-4.

Referring back to the configuration shown in FIG. 8, the Zener diodes 130 were in contact with the pads 121, which was made possible because and the pads and the electrical connections 123 were provided on the same plane. In the present disclosure, however, the pads 234 include metal blocks 250 having a height (h2) (see FIG. 16), meaning that the metal blocks 250 are not provided on the same plane. Accordingly, the first, third, and fourth electrical connections 232-1, 232-3, and 232-4 on the same plane can be electrically connected to the second electrical connection 232-2.

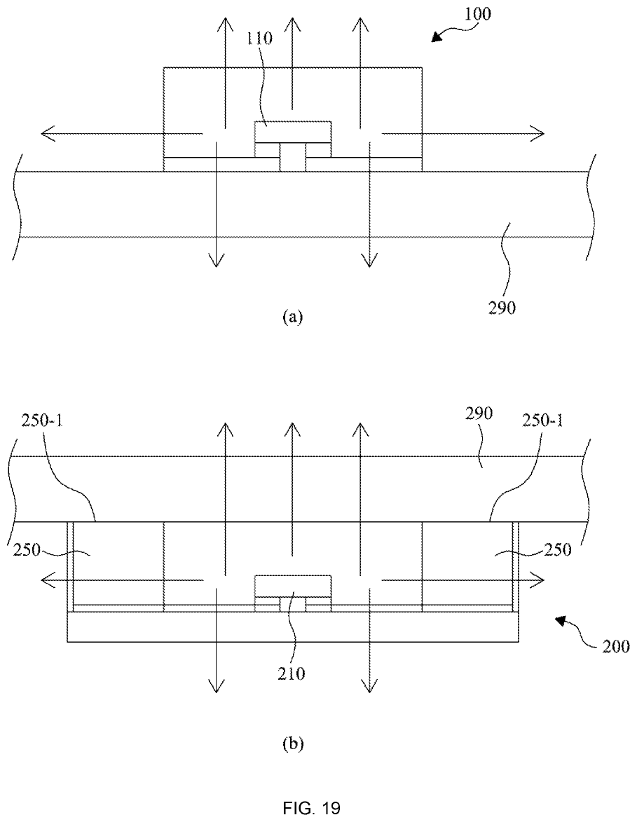

FIG. 19 illustrates applications of a semiconductor light emitting device of the present disclosure to a transparent substrate.

The semiconductor light emitting chips 110 and 210 of FIGS. 19A and 19B are formed of flip chips. As can be seen from the drawings, a majority portion of the light escapes through the upper surfaces of the semiconductor light emitting chips 110 and 210.

In the semiconductor light emitting device 100 of FIG. 19A, although a portion of the light may escape through the transparent substrate 290, a majority portion of the light escapes through the upper surface of the semiconductor light emitting chip 110, in the opposite direction to the transparent substrate 290. Here, the transparent substrate may be a transparent PCB, for example.

On the other hand, the semiconductor light emitting device 200 in FIG. 19B is electrically connected to the transparent substrate 290 through the upper surfaces 250-1 of the metal blocks 250, and a majority portion of the light of the semiconductor light emitting device 200 will escape through the transparent substrate 290.

Since the plate 231 semiconductor light emitting device 200 may be made from glass or sapphire, it can be difficult to connect the plate 230 directly electrically to the transparent substrate 290. Especially when the plate 231 of the semiconductor light emitting device 200 needs to be attached to the transparent substrate 290 as shown in FIG. 19A, it may be necessary to form electrical connections on the upper and lower surfaces of the plate 231 and holes for interconnecting the electrical connections. Optionally, the holes can be formed by laser drill processing. Due to high setup costs and lengthy processing time of the laser drill processing, however, the present disclosure has adopted the metal electrodes 250 as shown in FIG. 19B, such that electrical connections to the transparent substrate 290 are made possible without holes, thereby saving the time and cost.

Set out below are a series of clauses that disclose features of further exemplary embodiments of the present disclosure, which may be claimed.

(1) A semiconductor light emitting device, comprising: at least one semiconductor light emitting chip, with each chip including a plurality of electrodes; a plurality of pads arranged at a designated distance from the plurality of electrodes on a plane, respectively; electrical connections provided on the same plane as the plurality of pads for electrically connecting the electrodes and the pads, respectively; and an encapsulation member for covering the at least one semiconductor light emitting chip.

(2) There is also provided, the semiconductor light emitting device of clause (1) wherein: the electrical connections form multiple paths between the plurality of pads and the plurality of electrodes, respectively.

(3) There is also provided, the semiconductor light emitting device of clause (2) wherein: the electrical connections are formed in a net structure.

(4) There is also provided, the semiconductor light emitting device of clause (3) wherein: the electrical connections are formed in a uniform pattern.

(5) There is also provided, the semiconductor light emitting device of clause (4) wherein: the pattern of the electrical connections in contact with the plurality of pads or with the plurality of electrodes has a smaller size than the pattern of the electrical connections not in contact with the plurality of pads or with the plurality of electrodes.

(6) There is also provided, the semiconductor light emitting device of clause (1) wherein: the encapsulation member covers the electrical connections in such a manner that at least a portion of the electrical connections is exposed.

(7) There is also provided, the semiconductor light emitting device of clause (6) wherein: the encapsulation member covers the pads in such a manner that at least a portion of the pads is exposed.

(8) There is also provided, the semiconductor light emitting device of clause (1) wherein: the plurality of pads and the at least one semiconductor light emitting chip are arranged at a designated distance from each other, with the distance being equal to or greater than the width of the semiconductor light emitting chip.

(9) There is also provided, the semiconductor light emitting device of clause (1) wherein: the pad has a width greater than a width of the semiconductor light emitting chip.

(10) There is also provided, the semiconductor light emitting device of clause (1) wherein: the pads are projected out of the encapsulation member.

(11) There is also provided, the semiconductor light emitting device of clause (1) further comprising: a Zener diode adapted to prevent the application of a reverse voltage across the at least one semiconductor light emitting chip.

(12) There is also provided, the semiconductor light emitting device of clause (11) wherein: the Zener diode is provided on the pad.

(13) There is also provided, the semiconductor light emitting device of clause (1) wherein the at least one semiconductor light emitting chip comprises a first semiconductor light emitting chip including a first electrode and a second electrode, a second semiconductor light emitting chip including a third electrode and a fourth electrode, and a third semiconductor light emitting chip including a fifth electrode and a sixth electrode; wherein the pads comprises a first pad electrically connected to the first, third and fifth electrodes, a second pad electrically connected to the second electrode, a third pad electrically connected to the fourth electrode, and a fourth pad electrically connected to the sixth electrode; and wherein the electrical connections comprise a first electrical connection for electrically connecting the first pad, the first electrode, the third electrode and the fifth electrode, a second electrical connection for electrically connecting the second pad and the second electrode, a third electrical connection for electrically connecting the third pad and the third electrode, and a fourth electrical connection for electrically connecting the fourth pad and the fourth electrode.

(14) There is also provided, the semiconductor light emitting device of clause (1) comprising: a plurality of Zener diodes adapted to prevent the application of a reverse voltage across the first, second, and third semiconductor light emitting devices, respectively.

(15) There is also provided, the semiconductor light emitting device of clause (14) wherein: the plurality of Zener diodes is provided on the second, third and fourth pads, respectively.

(16) A method for manufacturing a semiconductor light emitting device including at least one semiconductor light emitting chip, the method comprising: preparing a substrate; providing the at least one semiconductor light emitting chip on the substrate; providing an encapsulation member over the substrate and the semiconductor light emitting chips; removing the substrate; and forming, on the encapsulation member, electrical connections between pads and the semiconductor light emitting chips, respectively, with each of the pads being arranged at a designated distance from each of the light emitting chips.

(17) There is also provided, the method for manufacturing a semiconductor light emitting device of clause (16) wherein: providing the at least one semiconductor light emitting chip on the substrate includes providing Zener diodes corresponding to the at least one semiconductor light emitting chip, with each of the Zener diodes being arranged at a designated distance from each of the at least one semiconductor light emitting chip.

(18) A method for manufacturing a semiconductor light emitting device including at least one semiconductor light emitting chip, the method comprising: preparing a substrate; forming, on the substrate, electrical connections for connecting a plurality of pads and the at least one semiconductor light emitting chip, respectively, with the plurality of pads being arranged at a designated distance from the semiconductor light emitting chips; providing the at least one semiconductor light emitting chip on the substrate; providing an encapsulation member over the substrate and the semiconductor light emitting chips; and removing the substrate.

(19) There is also provided, the method for manufacturing a semiconductor light emitting device of clause (18) wherein: providing the at least one semiconductor light emitting chip on the substrate includes providing, on the plurality of pads, Zener diodes corresponding to the at least one semiconductor light emitting chip.

(20) A semiconductor light emitting device, comprising: a semiconductor light emitting chip including a first electrode and a second electrode; a substrate including a plate on which electrical connections are formed, with the electrical connections including a first electrical connection electrically connected to the first electrode and a second electrical connection electrically connected to the second electrode; and metal blocks provided on the substrate, with the metal blocks including a first metal block that includes an upper surface electrically connected to an external substrate and a lower surface electrically connected to the first electrical connection, and a second metal block that includes an upper surface electrically connected to an external substrate and a lower surface electrically connected to the second electrical connection, wherein the metal blocks have a height equal to or greater than that of the semiconductor light emitting chip.

(21) There is also provided, the semiconductor light emitting device of clause (20) wherein: the metal blocks are arranged at a designated distance from the semiconductor light emitting chip.

(22) There is also provided, the semiconductor light emitting device of clause (20) wherein: the substrate is transparent.

(23) There is also provided, the semiconductor light emitting device of clause (20) wherein: the plate is made from a transparent material, and the electrical connections have multiple paths.

(24) There is also provided, the semiconductor light emitting device of clause (20) further comprising: an encapsulation member for enclosing the first and second metal blocks in such a manner that upper surfaces of the first and second metal blocks are exposed, and for covering the semiconductor light emitting chip and the substrate.

(25) There is also provided, the semiconductor light emitting device of clause (20) wherein: the first electrical connection includes a first contact portion in contact with the first electrode, a first pad in contact with the first metal block, and a first connection portion for electrically connecting the first contact portion and the first pad; and the second electrical connection includes a second contact portion in contact with the second electrode, a second pad in contact with the second metal block, and a second connection portion for electrically connecting the second contact portion and the second pad, with the first pad being provided under the first metal block, and the second pad being provided under the second metal block.

(26) There is also provided, the semiconductor light emitting device of clause (25) wherein: the first connection portion and the second connection portion are formed in a net structure.

(27) There is also provided, the semiconductor light emitting device of clause (25) further comprising: a second semiconductor light emitting device including a third electrode and a fourth electrode, and a third semiconductor light emitting device including a fifth electrode and a sixth electrode, wherein the metal blocks further include a third metal block and a fourth metal block, with the first metal block being electrically connected to the first electrode, the second metal block being electrically connected to the second, fourth, and sixth electrodes, the third metal block being electrically connected to the third electrode, and the fourth metal block being electrically connected to the firth electrode; and wherein the electrical connections include a first electrical connection formed between the first metal block and the first electrode, a second electrical connection formed between the second block and the second, fourth and sixth electrodes, a third electrical connection formed between the third metal block and the third electrode, and a fourth electrical connection formed between the fourth metal block and the fifth electrode.

(28) There is also provided, the semiconductor light emitting device of clause (20) wherein: the electrical connections connect the semiconductor light emitting chip and the metal blocks through multiple paths therebetween.

A semiconductor light emitting device according to an exemplary embodiment of the present disclosure has thinner electrical connections in a net structure, making the semiconductor light emitting device more visible.

A semiconductor light emitting device according to another exemplary embodiment of the present disclosure has electrical connections forming multiple paths between the pads and the electrodes, such that the pads and the electrodes stay electrically connected even if one of the paths may be cut off or disconnected.

A semiconductor light emitting device according to another exemplary embodiment of the present disclosure is configured so that the electrical connections and the pads are arranged inside the encapsulation member, preventing separation between them.

With a method for manufacturing a semiconductor light emitting device according to an exemplary embodiment of the present disclosure, the semiconductor light emitting device is configured so that the electrical connections are projected out of the encapsulation member.

With a method for manufacturing a semiconductor light emitting device according to another exemplary embodiment of the present disclosure, the semiconductor light emitting device is configured so that the electrical connections and the pads are arranged inside the encapsulation member, exposing only a portion of each.

A semiconductor light emitting device according to another exemplary embodiment of the present disclosure is configured to emit lights from six sides.

A semiconductor light emitting device according to another exemplary embodiment of the present disclosure is configured so that metal blocks connected to an external substrate are provided along the direction of lights escaping from the semiconductor light emitting chip.

With a method for manufacturing a semiconductor light emitting device according to another exemplary embodiment of the present disclosure, the semiconductor light emitting device is protected against warpage.

What is claimed is:

1. A semiconductor light emitting device, comprising:
at least one semiconductor light emitting chip, with each chip including a plurality of electrodes;
a plurality of pads arranged at a designated distance from the plurality of electrodes on a plane, respectively;
electrical connections provided on the same plane as the plurality of pads for electrically connecting the electrodes and the pads, respectively; and
an encapsulation member for covering the at least one semiconductor light emitting chip.

2. The semiconductor light emitting device of claim 1, wherein the electrical connections form multiple paths are formed between the plurality of pads and the plurality of electrodes, respectively.

3. The semiconductor light emitting device of claim 2, wherein the electrical connections are formed in a net structure.

4. The semiconductor light emitting device of claim 3, wherein the electrical connections are formed in a uniform pattern.

5. The semiconductor light emitting device of claim 4, wherein the pattern of the electrical connections in contact with the plurality of pads or with the plurality of electrodes has a smaller size than the pattern of the electrical connections not in contact with the plurality of pads or with the plurality of electrodes.

6. The semiconductor light emitting device of claim 1, wherein the encapsulation member covers the electrical connections in such a manner that at least a portion of the electrical connections is exposed.

7. The semiconductor light emitting device of claim 6, wherein the encapsulation member covers the pads in such a manner that at least a portion of the pads is exposed.

8. The semiconductor light emitting device of claim 1, wherein the plurality of pads and the at least one semiconductor light emitting chip are arranged at a designated distance from each other, with the distance being equal to or greater than the width of the semiconductor light emitting chip.

9. The semiconductor light emitting device of claim 1, wherein the pad has a width greater than a width of the semiconductor light emitting chip.

10. The semiconductor light emitting device of claim 1, wherein the pads are projected out of the encapsulation member.

11. The semiconductor light emitting device of claim 1, further comprising: a Zener diode adapted to prevent the application of a reverse voltage across the at least one semiconductor light emitting chip.

12. The semiconductor light emitting device of claim 11, wherein the Zener diode is provided on the pad.

13. The semiconductor light emitting device of claim 1, wherein the at least one semiconductor light emitting chip comprises a first semiconductor light emitting chip including a first electrode and a second electrode, a second semiconductor light emitting chip including a third electrode and a fourth electrode, and a third semiconductor light emitting chip including a fifth electrode and a sixth electrode;
wherein the pads comprises a first pad electrically connected to the first, third and fifth electrodes, a second pad electrically connected to the second electrode, a third pad electrically connected to the fourth electrode, and a fourth pad electrically connected to the sixth electrode; and
wherein the electrical connections comprise a first electrical connection for electrically connecting the first pad, the first electrode, the third electrode and the fifth electrode, a second electrical connection for electrically connecting the second pad and the second electrode, a third electrical connection for electrically connecting the third pad and the third electrode, and a fourth electrical connection for electrically connecting the fourth pad and the fourth electrode.

14. The semiconductor light emitting device of claim 1, comprising: a plurality of Zener diodes adapted to prevent the application of a reverse voltage across the first, second, and third semiconductor light emitting devices, respectively.

15. The semiconductor light emitting device of claim 14, wherein the plurality of Zener diodes is provided on the second, third and fourth pads, respectively.

16. A method for manufacturing a semiconductor light emitting device including at least one semiconductor light emitting chip, the method comprising:
preparing a substrate;
providing the at least one semiconductor light emitting chip on the substrate;
providing an encapsulation member over the substrate and the semiconductor light emitting chips;
removing the substrate; and
forming, on the encapsulation member, electrical connections between pads and the semiconductor light emitting chips, respectively, with each of the pads being arranged at a designated distance from each of the light emitting chips.

17. The method of claim 16, wherein providing the at least one semiconductor light emitting chip on the substrate includes providing Zener diodes corresponding to the at least one semiconductor light emitting chip, with each of the Zener diodes being arranged at a designated distance from each of the at least one semiconductor light emitting chip.

18. A method for manufacturing a semiconductor light emitting device including at least one semiconductor light emitting chip, the method comprising:
preparing a substrate;
forming, on the substrate, electrical connections for connecting a plurality of pads and the at least one semiconductor light emitting chip, respectively, with the plurality of pads being arranged at a designated distance from the semiconductor light emitting chips;
providing the at least one semiconductor light emitting chip on the substrate;
providing an encapsulation member over the substrate and the semiconductor light emitting chips; and
removing the substrate.

19. The method of claim 18, wherein providing the at least one semiconductor light emitting chip on the substrate includes providing, on the plurality of pads, Zener diodes corresponding to the at least one semiconductor light emitting chip.
